(19) United States
(12) Patent Application Publication
(10) Pub. No.: US 2025/0210380 A1
(43) Pub. Date: Jun. 26, 2025

(54) BARRIER LAYER REMOVAL DEVICE AND BARRIER LAYER REMOVAL METHOD

(71) Applicant: SAMSUNG ELECTRONICS CO., LTD., SUWON-SI (KR)

(72) Inventors: Tae Oh HA, Suwon-si (KR); Jongho PARK, Suwon-si (KR); Chanwook PARK, Suwon-si (KR); Hyungjun PARK, Suwon-si (KR); Jaemok JUNG, Suwon-si (KR); Hongseo HEO, Suwon-si (KR)

(21) Appl. No.: 18/754,531

(22) Filed: Jun. 26, 2024

(30) Foreign Application Priority Data
Dec. 26, 2023 (KR) 10-2023-0191126

(51) Int. Cl. H01L 21/67; H01L 21/02; H01L 21/683

(52) U.S. Cl. CPC H01L 21/6708; H01L 21/02076; H01L 21/6836

(57) ABSTRACT

Disclosed is a barrier layer removal device including: a frame mounted with a tape to which a wafer is attached, wherein the wafer includes a barrier layer disposed on one surface, a support on which the wafer, attached to the tape, is disposed, a frame cover disposed above the frame, wherein the frame fixes the wafer on the support by pressing an edge region of the one surface of the wafer and a nozzle for spraying an etchant on the barrier layer of the wafer.

### CROSS-REFERENCE TO RELATED APPLICATION

This application claims priority under 35 U.S.C. § 119 to Korean Patent Application No. 10-2023-0191126, filed on Dec. 26, 2023, in the Korean Intellectual Property Office, the disclosure of which is incorporated by reference herein in its entirety.

### (a) TECHNICAL FIELD

The present disclosure relates to a barrier layer removal device and a barrier layer removal method.

### (b) DISCUSSION OF THE RELATED ART

In a semiconductor industry, a barrier layer, such as a titanium (Ti) layer, is formed between a carrier substrate and a wafer to prevent wafer contamination while removing the carrier substrate. The barrier layer is often removed by attaching the wafer to a tape mounted on a ring frame, debonding the carrier substrate from the wafer, and then spraying an etchant thereon.

A method in which a ring frame cover comes into contact with the tape and vacuum-suctions the wafer below the tape holds the wafer in place during the removal of the barrier layer. When using this method, delamination occurs between the tape and the wafer due to warpage of the wafer, the etchant of the barrier layer, or the etc. The delamination occurring between the tape and the wafer causes a lower yield due to ingress of foreign materials into the wafer, poor connection of solder balls, or the like.

### SUMMARY OF THE INVENTION

The present disclosure provides a barrier layer removal device and method that reduces delamination between a tape and a wafer.

According to an embodiment of the present disclosure, provided is a barrier layer removal device including: a frame mounted with a tape to which a wafer is attached, wherein the wafer includes a barrier layer disposed on one surface, a support on which the wafer, attached to the tape, is disposed, a frame cover disposed above the frame, wherein the frame fixes the wafer on the support by pressing an edge region of the one surface of the wafer and a nozzle for spraying an etchant on the barrier layer of the wafer.

According to an embodiment of the present disclosure, provided is a barrier layer removal device including: a frame mounted with a tape to which a wafer is attached, wherein the wafer includes a barrier layer disposed on a first surface, a support on which the wafer, attached to the tape, is disposed, a frame cover disposed above the frame, wherein the frame cover fixes the wafer on the support by pressing an edge region of the first surface of the wafer, a plurality of contact pins respectively pressing the edge regions of the first surface of the wafer together with the frame cover and a nozzle for spraying an etchant on the barrier layer of the wafer.

According to an embodiment of the present disclosure, provided is a barrier layer removal method including: mounting a tape on a frame, attaching a wafer to the tape, wherein the wafer includes a barrier layer, disposing the wafer, which is attached to the tape, on a support, fixing the wafer on the support by pressing a surface of the wafer and removing the barrier layer by spraying an etchant on the barrier layer.

### BRIEF DESCRIPTION OF THE DRAWINGS

FIG. 1 is a cross-sectional view of a wafer structure including a wafer disposed on a carrier substrate.

FIGS. 2 and 3 each illustrate a process of removing the carrier substrate and a bonding layer.

FIG. 4 illustrates a case where a frame cover presses a tape in a comparative example.

FIG. 5 illustrates a case where the frame cover presses the wafer together with a contact pin according to an embodiment.

FIG. 6 is a view for explaining a position where the wafer is pressed.

FIG. 7 illustrates a process of spraying an etchant on the wafer.

FIG. 8 illustrates a wafer rinsing process.

FIG. 9 is a schematic flowchart of a barrier layer removal method according to an embodiment.

### DETAILED DESCRIPTION OF THE EMBODIMENTS

Hereinafter, embodiments of the present disclosure are described in detail with reference to the accompanying drawings so that those skilled in the art to which the present disclosure pertains may easily practice the present disclosure. The present disclosure may be implemented in various different forms and is not necessarily limited to the embodiments described herein.

To the extent that an element has not been described in detail, it may be assumed that the element is at least similar to corresponding elements that have been described in previous figures.

In addition, the size and thickness of each component shown in the accompanying drawings are shown for convenience of explanation, and therefore, the present disclosure is not necessarily limited to contents shown in the drawings. The thicknesses are exaggerated in the drawings in order to clearly represent several layers and regions. In addition, the thicknesses of some layers and regions are exaggerated in the drawings for convenience of explanation.

Throughout the specification, when any one part is referred to as being “connected to” another part, it means that any one part and another part are “directly connected to” each other or “indirectly connected to” each other with the other part interposed therebetween. In a similar viewpoint, such a connection may include not only a “physical connection” but also an “electrical connection” between the two parts.

In addition, when an element such as a layer, a film, a region or a substrate is referred to as being “on” or “above” another element, the element may be “directly on” another element or may have a third element interposed therebetween. On the other hand, when an element is referred to as being “directly on” another element, there is no third element interposed therebetween. In addition, when an element is referred to as being “on” or “above” a reference element, the element may be disposed on or below the reference element, and may not necessarily be “on” or “above” the reference element in an opposite direction of gravity.

In addition, throughout the specification, an expression “on a plane” may indicate a case where a target is viewed from the top, and an expression “on a cross-section” may indicate a case where a cross-section of the target taken along a vertical direction is viewed from its side.

In addition, throughout the specification, a sequential number such as a first, a second, or the like is used to distinguish a specific component from another component which is the same or similar to the specific component, and is not necessarily intended to refer to the specific component. Accordingly, a component referred to as a first component in a specific portion of the specification may also be referred to as a second component in another portion of the specification.

In addition, throughout the specification, a term of a single number may include its plural number unless explicitly indicated otherwise in the context.

In addition, throughout the specification, terms of one surface and the other surface are intended to distinguish surfaces different from each other, and are not necessarily intended to limit the corresponding surface to a specific surface. Accordingly, the surface referred to as one surface in a specific portion of the specification may also be referred to as the other surface in another portion of the specification.

Hereinafter, the embodiments of the present disclosure are described with reference to the drawings.

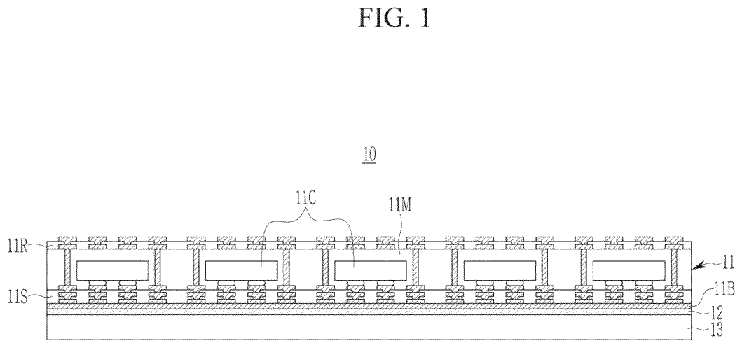

FIG. 1 is a cross-sectional view of a wafer structure including a wafer disposed on a carrier substrate.

A wafer structure 10 may include a wafer 11 including a barrier layer 11B disposed on one surface, a carrier substrate 13 on which the wafer 11 is disposed, and a bonding layer 12 disposed between the wafer 11 and the carrier substrate 13. In the specification, the barrier layer 11B is described as a component included in the wafer 11 for convenience of explanation. In addition, the same reference number is used for the wafer 11 before and after the barrier layer 11B is removed therefrom.

The wafer 11 may be a reconstituted wafer in which semiconductor chips are reorganized into a wafer form. The reconstituted wafer may include a substrate 11S, a plurality of semiconductor chips 11C disposed on the substrate 11S while being spaced apart from each other, a molding material 11M for molding the plurality of the semiconductor chips 11C on the substrate 11S, and a rewiring structure 11R disposed on the molding material 11M and electrically connected to the substrate 11S. The reconstituted wafer may be diced along a dicing line in a subsequent process, which allows an individual semiconductor package to be manufactured.

The rewiring structure 11R of the reconstituted wafer may be electrically connected to the substrate 11S, for example, through a conductive post, and electrically connect the semiconductor package to another semiconductor package disposed thereon in a package on package (POP) structure. However, the wafer 11 might not include the rewiring structure 11R.

The barrier layer 11B may be disposed on the substrate 11S and may prevent the wafer 11 from being contaminated when removing the carrier substrate 13 and the bonding layer 12 therefrom. The barrier layer 11B may be a metal layer, and include, for example, titanium (Ti).

The bonding layer 12 may be disposed between the carrier substrate 13 and the barrier layer 11B to thus attach these two components to each other. For example, a bottom surface of the bonding layer 12 may be in direct contact with a top surface of the carrier substrate 13. The bonding layer 12 may be made of, for example, a photoimageable dielectric (PID).

The carrier substrate 13 may serve as a support substrate in a manufacturing process of the wafer 11. The carrier substrate 13 is not necessarily limited to any particular type, and may be, for example, a glass carrier substrate.

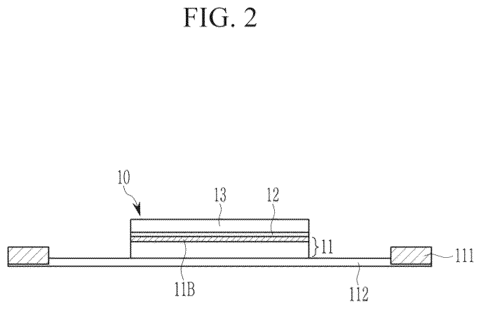

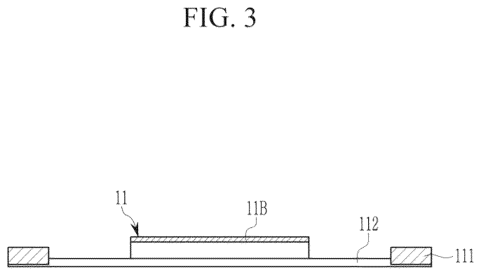

FIGS. 2 and 3 each illustrate a process of removing the carrier substrate and the bonding layer.

Referring to FIG. 2, the wafer structure 10 may first be attached to a tape 112 mounted on a frame 111. Here, in the wafer structure 10, the wafer 11 may include a surface opposite to the one on which its barrier layer 11B is disposed and attached to the tape 112. For example, the rewiring structure 11R of the wafer 11 may be attached to the tape 112. Alternatively, another component, such as the molding material 11M, may be attached to the tape 112 when the wafer 11 does not include the rewiring structure 11R.

The frame 111 may be a frame having a shape of a ring with a through hole, and the tape 112 may be attached to one surface of the frame and have a central region exposed through the through hole of the frame 111. Accordingly, the wafer structure 10 may be attached to the tape 112 by being disposed on the tape 112 in the through hole of the frame 111. A diameter of the wafer 11 may be about 300 mm, and a diameter of the tape 112 may be about 400 mm. A process performed while the wafer 11 is attached to the frame 111 may be referred to as a 400 mm process, and a process performed before the wafer 11 is attached to the frame 111 may be referred to as a 300 mm process.

Referring to FIG. 3, the barrier layer 11B may be exposed by first removing the carrier substrate 13 and the bonding layer 12 from the wafer 11. The carrier substrate 13 may be removed, for example, by laser delamination, and the bonding layer 12 may be removed by a descum process using plasma.

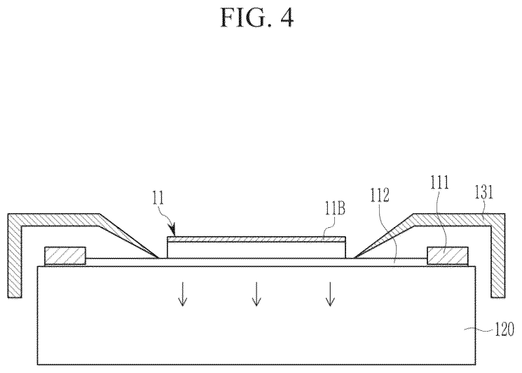

FIG. 4 illustrates a case where a frame cover presses the tape in a comparative example.

A frame cover 131 may be disposed above the frame 111 and at least partially cover the frame 111, thereby protecting the frame 111 from an etchant during an etchant spray. In addition, the frame cover 131 may fix the wafer 11, attached to the tape 112, onto a support 120 by pressing the tape 112.

Here, support 120 may vacuum-suction the tape 112 and the wafer 11, and fix the tape 112 and the wafer 11 onto the support 120 together with the frame cover 131 by pressing the tape 112.

As illustrated in the case of FIG. 4, when the frame cover 131 is in contact with the tape 112, delamination may occur between the tape 112 and the wafer 11 because of warping caused by variations in coefficients of thermal expansion (CTE) of the respective components included in the wafer 11, the etchant of the barrier layer, or the like. For example, the warpage may occur where a peripheral region of the wafer 11 experiences more severe delaminated than the central region, causing delamination between the peripheral region of the wafer 11 and the tape 112. Alternatively, the etchant of the barrier layer 11B may flow into an interface between the wafer 11 and the tape 112, leading to delamination between the tape 112 and the wafer 11. The delamination may cause a lower yield due to the inflow of foreign materials into the wafer, poor connection of solder balls, or the like.

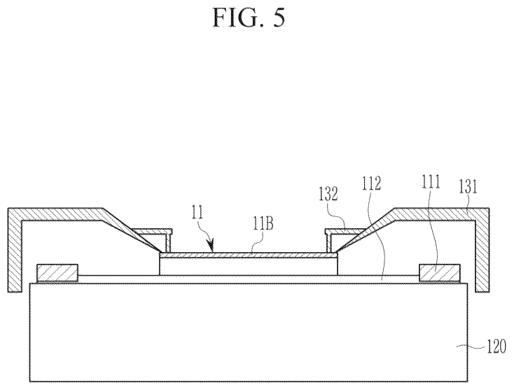

FIG. 5 illustrates a case where the frame cover presses the wafer together with a contact pin according to an embodiment.

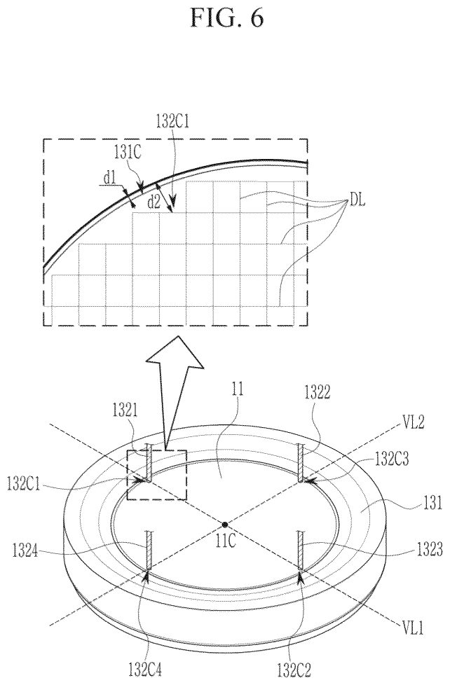

FIG. 6 is a view for explaining a position where the wafer is pressed.

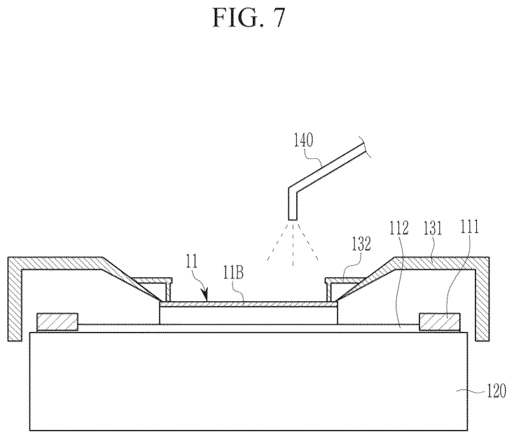

FIG. 7 illustrates a process of spraying the etchant on the wafer.

Referring to FIGS. 5 to 7, the barrier layer removal device may include the frame 111 mounted with the tape 112, the support 120 on which the wafer 11, attached to the tape 112, is disposed, the frame cover 131 protecting the frame 111 from the etchant, a contact pin 132 pressing the wafer 11, and a nozzle 140 for spraying the etchant on the barrier layer 11B. As described above, the wafer 11 may include the barrier layer 11B disposed on its one surface. The wafer 11 may be disposed on the support 120 while having the other surface attached to the tape 112 which is mounted on the frame 111.

Unlike the comparative example, the support 120 might not vacuum-suction the wafer 11 when the frame cover 131 and the contact pin 132 press the wafer 11. The support 120 may vacuum-suction the wafer 11 together with the tape 112 when the frame cover 131 and the contact pin 132 press the wafer 11. In this case, the delamination between the wafer 11 and the tape 112 may occur, which might not be desirable.

A frame cover 131 may be disposed above the frame 111 and at least partially cover the frame 111, thereby protecting the frame 111 from the etchant during the etchant spray. In addition, in the present disclosure, the frame cover 131 may fix the wafer 11 to the support 120 by pressing an edge region of one surface of the wafer 11. In other words, the frame cover 131 may secure the wafer 11 to the support 120 by pressing the edge region of one surface of the wafer 11.

The frame cover 131 may press the edge region of one surface of the wafer 11 along a circumference of the wafer 11. Here, “following the circumference of the wafer 11” refers to connecting points of the wafer 11 that are a predetermined distance away from its edge. The frame cover 131 may, for example, press a portion disposed within 1 mm from its edge along the circumference of the wafer 11. For example, the frame cover 131 may press points 131C away by about 1 mm, 0.9 mm, 0.8 mm, or 0.5 mm from the edge of the wafer 11, along the circumference of the wafer 11. For example, a distance dl between the points 131C pressed by the frame cover 131 and the edge of the wafer 11 may be about 1 mm or less. Alternatively, the frame cover 131 may press an entire region disposed within about 1 mm from the edge of the wafer 11.

At least one contact pin 132 may press the edge region of one surface of the wafer 11 together with the frame cover 131. The wafer 11 may be more stably fixed to the support 120 when the contact pin 132 further presses the wafer 11. The contact pin 132 may be a component coupled to the frame cover 131 or a component separate from the frame cover 131. The wafer 11 may be sufficiently fixed to the support 120 by using only the frame cover 131, and in this case, the contact pin 132 might not be used.

The frame cover 131 may at least partially cover the frame 111 disposed outside the wafer 11 and may extend towards the edge region of the wafer 11. Therefore, the contact pin 132 may press a point inside the wafer 11 rather than the portion pressed by the frame cover 131.

However, the contact pin 132 may press a region that will be removed after dicing to prevent damage to the wafer's 11 functionality. Accordingly, the contact pin 132 may press a point outside the intersections of the wafer 11 dicing lines.

For example, the contact pin 132 may press a point disposed within about 5 mm from the edge of the wafer 11. In other words, a distance d2 between the point pressed by the contact pin 132 and the edge of the wafer 11 may be about 5 mm or less.

The number of the contact pins 132 is not particularly limited. However, it may be desirable to have two or more contact pins 132 for the stable fixation of the wafer 11. For example, the contact pins 132 may include a first contact pin 1321 and a second contact pin 1322, each pressing points disposed on a plane in opposite directions from a center 11C of one surface of the wafer 11. In some embodiments, the contact pins 132 may further include a third contact pin 1323 and a fourth contact pin 1324, each pressing points disposed on the plane in opposite directions from the center 11C of one surface of the wafer 11. A first virtual line VL1 and a second virtual line VL2 may intersect each other. The first virtual line VL1 connects a point 132C1, pressed by the first contact pin 1321 of the wafer 11, with a point 132C2, pressed by the second contact pin 1322. The second virtual line VL2 connects a point 132C3, pressed by the third contact pin 1323 of the wafer 11, with a point 132C4, pressed by the fourth contact pin 1324. The first virtual line VL1 and the second virtual line VL2 may form approximately a right angle, but this is not necessarily a limitation.

The nozzle 140 may spray the etchant on the barrier layer 11B of the wafer 11. The nozzle 140 may be, for example, a swing nozzle, and may move towards the wafer 11 to spray the etchant on the barrier layer 11B.

According to the present disclosure, the wafer 11 may be pressed using the frame cover 131 and/or the contact pin 132 and fixed on the support 120. The wafer 11 may be pressed in a direction in which the tape 112 is disposed, thereby preventing delamination between the tape 112 and the wafer 11. This prevents lower yield caused by foreign material inflow into the wafer, the poor connection of the solder balls, or the like.

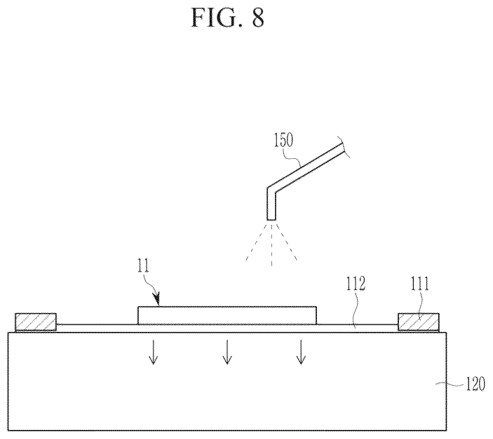

FIG. 8 illustrates a wafer rinsing process.

The frame cover 131 and the contact pin 132, which come into contact with and press the wafer 11, may be moved above the wafer 11 to be detached from the wafer 11. The rinsing process may then be performed by spraying deionized water on the wafer 11 by using a nozzle 150. The nozzle 150 used in the rinsing process may also be the swing nozzle and may be moved above the wafer 11 to spray the deionized water thereon.

After the rinsing process, the wafer may be dried through a drying process. The drying process may be performed, for example, by supplying a drying fluid to the wafer 11 or by applying a centrifugal force thereto.

During the rinsing and drying processes, the frame cover 131 may be detached from the wafer 11, and the support 120 may fix the tape 112 and the wafer 11 on the support 120 by vacuum-suctioning the same. For example, the support 120 may vacuum-suction the edge region and central region of the wafer 11.

After the rinsing and drying processes, a process of debonding the wafer 11 from the tape 112 may be performed. The wafer 11 may be debonded from the tape 112, for example, by applying heat to the tape 112 to which the wafer 11 is attached or by irradiating ultraviolet (UV) light. The tape 112 may be, for example, a dicing tape.

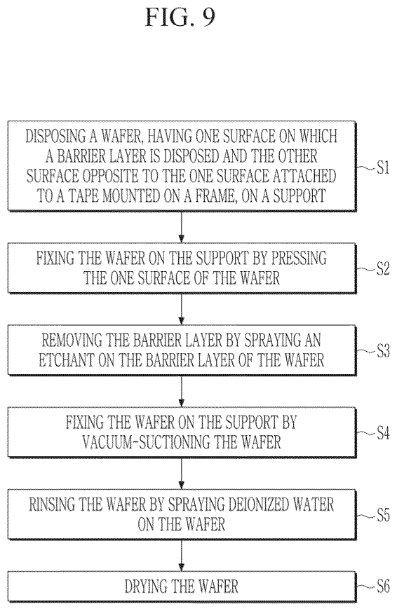

FIG. 9 is a schematic flowchart of a barrier layer removal method according to an embodiment.

Referring to FIG. 9, the barrier layer removal method may include: disposing the wafer 11, having one surface (e.g., a first surface) on which a barrier layer 11B is disposed and the other surface (e.g., a second surface) attached to a tape 112 mounted on a frame 111, on a support 120 (S1); fixing the wafer 11 on the support 120 by pressing one surface of the wafer 11 (S2); removing the barrier layer 11B by spraying an etchant on the barrier layer 11B of the wafer 11 (S3); fixing the wafer 11 on the support 120 by vacuum-suctioning the wafer 11 (S4); rinsing the wafer 11 by spraying deionized water on the wafer 11 (S5); and drying the wafer 11 (S6).

Before disposing the wafer 11 on the support 120 (S1), the tape 112 may be mounted on the frame 111, and the wafer 11, including the barrier layer 11B, may be attached to the tape 112. When attaching the wafer 11, including the barrier layer 11B to the tape 112, the surface of the wafer 11 opposite to the one with the barrier layer 11B may be attached to the tape 112.

When disposing the wafer 11 on the support 120 (S1), the wafer 11 may be disposed on the support 120 by bringing the tape 112 mounted on the frame 111 into contact with the support 120.

The fixing of the wafer 11 on the support 120 (S2) may be performed by pressing the edge region of the surface of the wafer 11 on which the barrier layer 11B is disposed. For example, this can be achieved by using the frame cover 131 to press the edge region of the wafer 11 along its circumference. In some embodiments, the fixing of the wafer 11 on the support 120 (S2) may be performed by further pressing two or more points in the edge regions of the surface of the wafer 11. For example, the points disposed on the plane in the opposite directions from the center 11C of the surface of the wafer 11 may respectively be pressed using the above-described first contact pin 1321 and the second contact pin 1322.

The removing of the barrier layer 11B (S3) may be performed, for example, by spraying the etchant on the barrier layer 11B of the wafer 11 by using the nozzle 140.

In the fixing of the wafer 11 on the support 120 (S2) and the removing of the barrier layer 11B (S3), the wafer 11 may be directly pressed using the frame cover 131, the contact pin 132, or the like to be fixed on the support 120, thus not requiring the vacuum-suction. However, delamination between the wafer 11 and the tape 112 may occur when the support 120 vacuum-suctions the wafer 11 and the tape 112 together, which might not be desirable.

Therefore, the fixing of the wafer 11 on the support 120 (S4) by vacuum-suctioning the wafer 11 may be performed after the fixing of the wafer 11 on the support 120 (S2) and the removing of the barrier layer 11B (S3). In the rinsing of the wafer 11 (S5) and the drying of the wafer 11 (S6), the frame cover 131 pressing the wafer 11 may be detached from the wafer 11. Therefore, the vacuum-suction may be used in fixing the wafer 11.

The rinsing of the wafer 11 (S5) may be performed, for example, by spraying the deionized water on the wafer 11 by using the nozzle 150. In addition, the drying of the wafer 11 (S6) may be performed, for example, by supplying the drying fluid to the wafer 11 or applying the centrifugal force thereto.

Although the embodiments of the present disclosure have been described in detail hereinabove, the scope of the present disclosure is not necessarily limited thereto, and may include several modifications and alterations made by those skilled in the art.

What is claimed is:

1. A barrier layer removal device, comprising:
a frame mounted with a tape to which a wafer is attached, wherein the wafer includes a barrier layer disposed on one surface;
a support on which the wafer, attached to the tape, is disposed;
a frame cover disposed above the frame, wherein the frame fixes the wafer on the support by pressing an edge region of the one surface of the wafer; and
a nozzle for spraying an etchant on the barrier layer of the wafer.

2. The device of claim 1, further comprising
a contact pin pressing the edge region of the one surface of the wafer together with the frame cover.

3. The device of claim 2, wherein
the contact pin presses a point inside the wafer rather than a portion of the wafer that is pressed by the frame cover.

4. The device of claim 3, wherein
the frame cover presses a portion disposed within about 1 mm from an edge of the wafer along a circumference of the wafer, and
the contact pin presses a point disposed within about 5 mm from the edge of the wafer.

5. The device of claim 2, wherein
the contact pin presses a point outside a point where dicing lines of the wafer intersect each other.

6. The device of claim 1, wherein
the support does not vacuum-suction the wafer when the frame cover presses the wafer.

7. The device of claim 1, wherein
the barrier layer is a metal layer.

8. The device of claim 7, wherein
the barrier layer includes titanium (Ti).

9. The device of claim 1, wherein
the wafer is a reconstituted wafer including a substrate, a plurality of semiconductor chips disposed on the substrate while being spaced apart from each other, and a molding material encapsulating the plurality of semiconductor chips on the substrate, and
wherein the barrier layer is disposed on the substrate.

10. The device of claim 9, wherein
the reconstituted wafer further includes a rewiring structure disposed on the molding material and electrically connected to the substrate.

11. A barrier layer removal device, comprising:
a frame mounted with a tape to which a wafer is attached, wherein the wafer includes a barrier layer disposed on a first surface;
a support on which the wafer, attached to the tape, is disposed;
a frame cover disposed above the frame, wherein the frame cover fixes the wafer on the support by pressing an edge region of the first surface of the wafer;
a plurality of contact pins respectively pressing the edge regions of the first surface of the wafer together with the frame cover; and
a nozzle for spraying an etchant on the barrier layer of the wafer.

12. The device of claim 11, wherein
the plurality of contact pins include a first contact pin and a second contact pin, each pressing points disposed on a plane in opposite directions from a center of the first surface of the wafer.

13. The device of claim 12, wherein
the plurality of contact pins further include a third contact pin and a fourth contact pin, each pressing points disposed on the plane in opposite directions from the center of the first surface of the wafer, and
wherein a first virtual line and a second virtual line intersect each other, the first virtual line connecting the point pressed by the first contact pin to the point pressed by the second contact pin, and the second virtual line connecting the point pressed by the third contact pin to the point pressed by the fourth contact pin.

14. A barrier layer removal method, comprising:
mounting a tape on a frame;
attaching a wafer to the tape, wherein the wafer includes a barrier layer;
disposing the wafer, which is attached to the tape, on a support;
fixing the wafer on the support by pressing a surface of the wafer; and
removing the barrier layer by spraying an etchant on the barrier layer.

15. The method of claim 14, wherein
the fixing of the wafer on the support is performed by pressing an edge region of the surface of the wafer.

16. The method of claim 15, wherein
the fixing of the wafer on the support is performed by pressing the edge region of the surface of the wafer along a circumference of the wafer.

17. The method of claim 16, wherein
the fixing of the wafer on the support is performed by further pressing two or more points in the edge regions of the surface of the wafer.

18. The method of claim 14, wherein
in the removing of the barrier layer, the support does not vacuum-suction the wafer.

19. The method of claim 14, further comprising:
rinsing the wafer by spraying deionized water on the wafer; and
drying the wafer.

20. The method of claim 19, wherein
in the rinsing of the wafer and the drying of the wafer, the support vacuum-suctions the wafer.
